(19) United States
(12) Patent Application Publication
(10) Pub. No.: US 2015/0189739 A1
(43) Pub. Date: Jul. 2, 2015

(54) PCB AND DISPLAY DEVICE HAVING THE PCB

(71) Applicant: SHENZHEN CHINA STAR OPTOELECTRONICS TECHNOLOGY CO., LTD, Shenzhen (CN)

(72) Inventors: Jianyong Fu, Shenzhen (CN); Dongsheng Guo, Shenzhen (CN); Jiehui Qin, Shenzhen (CN)

(21) Appl. No.: 14/235,094

(22) PCT Filed: Jan. 10, 2014
(86) PCT No.: PCT/CN2014/070436

§ 371 Date: Jan. 27, 2014

(30) Foreign Application Priority Data
Dec. 31, 2013 (CN) 201310753657.0

(51) Int. Cl. H05K 1/02

(52) U.S. Cl. CPC H05K 1/0225; H05K 2201/0715; H05K 2201/0355

(57) ABSTRACT

A printed circuit board (PCB) and a display device having the PCB include a substrate including a first surface that packages electronic components and a second surface opposite to the first surface, and a conductive foil that attaches to the second surface of the substrate. The conductive foil is divided into a plurality of blocks, and spacer regions are arranged between the blocks, where the spacer regions are configured with wires for electrical connection.

### TECHNICAL FIELD

The present disclosure relates to the field of manufacturing printed circuit boards (PCBs), and more particularly to the PCB and a display device having the PCB.

### BACKGROUND

As market competition of products increases, many manufacturers compress a printed circuit board (PCB) into a two-layer board to reduce cost. As shown in FIG. 1 and FIG. 2, a substrate 100 of the PCB having the two-layer board includes a first surface 110 that packages electronic components using surface mount technology (SMT) (a SMT area 111 is shown in FIG. 1), and a second surface 120 that attaches a conductive foil 121. In manufacturing the PCB, as adhesives binding the substrate 100 and the conductive foil 121 are affected by dip soldering or heat, volatile gas and heat generated is not easy to be removed, which causes the conductive foil 121 to thermally expand and fall, even warping the PCB. Thus, the electronic components cannot be mounted, the electronic components are in poor contact with soldering spots of the PCB, or bonding pads of some positions of the substrate cannot contract a soldering tin surface to make the tin not be soldered at the bonding pads. The above-mentioned problems need to be solved urgently.

### SUMMARY

In view of the above-described problems, the aim of the present disclosure is to provide a printed circuit board (PCB) and a display device having the PCB capable of good heat dissipation and avoiding a conductive foil falling.

The aim of the present disclosure is achieved by the following technical methods.

A printed circuit board (PCB) comprises a substrate comprising a first surface that packages electronic components and a second surface opposite to the first surface, and a conductive foil that attaches to the second surface of the substrate.

The conductive foil comprises a plurality of blocks, and spacer regions are arranged between the blocks, where the spacer regions are configured with wires for electrical connection.

Furthermore, the PCB is rectangular, and a long edge of the PCB is perpendicular to the spacer regions. Because proportion of thermal expansion of an entire conductive foil without the spacer regions is great at a long edge direction, the long edge of the PCB is perpendicular to the spacer regions, and the conductive foil is divides into a plurality of the blocks, which avoids proportion of the thermal expansion of the entire conductive foil increasing and falling, provides the buffer space for thermal expansion of the conductive foil, and achieves uniform heat dissipation. The heat is dissipated from the spacer regions instead of being concentrated in the interval between the substrate and the conductive foil.

Furthermore, the wires of the spacer region are arranged in the spacer region according to a same spacing, which improves electrical connection between the wires.

Furthermore, the wires of the spacer region are divided into a first group wire and a second group wire, where the first group wire and the second group wire are arranged in the spacer region according to themselves same spacing. Tire first group wire and the second group wire cross each other to form a net structure, which improves shielding effectiveness, and further effectively avoids an electro-magnetic interference (EMI).

Furthermore, the spacing between the wires is in a range of 0.13-0.5 mm, which effectively avoids the EMI and simplifies wire design, further avoids copper foil warping.

Furthermore, a width of the wire is in a range of 0.13-0.5 mm, which avoids the proportion of the thermal expansion of the conductive foil increasing and effectively avoids the EMI.

A liquid crystal display device comprises one or more PCBs, where the PCB comprises a substrate comprising a first surface that packages electronic components and a second surface opposite to the first surface, and a conductive foil that attaches to the second surface of the substrate.

The conductive foil comprises a plurality of blocks, spacer regions are arranged between the blocks, the spacer regions are configured with wires for electrical connection.

Furthermore, the PCB is rectangular, a long edge of the PCB is perpendicular to the spacer regions.

Furthermore, the wires of the spacer region are divided into a first group wire and a second group wire, where the first group wire and the second group wire are arranged in the spacer region according to themselves same spacing. The first group wire and the second group wire cross each other to form a net structure.

Furthermore, the spacing between the wires is in a range of 0.13-0.5 mm, and a width of the wire is in a range of 0.13-0.5 mm.

The conductive foil of the PCB of the present disclosure is divided into the plurality of blocks. Spacer regions are arranged between the blocks, where the blocks are electrically connected each other through the wires, and the spacer regions provide buffer space for thermal expansion of the conductive foil, and make the internal heat between the substrate and the conductive foil fast and uniformly pass out, which effectively prevents the conductive foil of the PCB falling and the substrate warping, further improving product yield and work life of the products.

### BRIEF DESCRIPTION OF FIGURES

FIG. 1 is a structural diagram of a first surface of a typical printed circuit board (PCB).

FIG. 2 is a structural diagram of a second surface of a typical PCB.

FIG. 3 is a structural diagram of a PCB of a first example of the present disclosure.

FIG. 4 is an improved structural diagram of a PCB of a first example of the present disclosure.

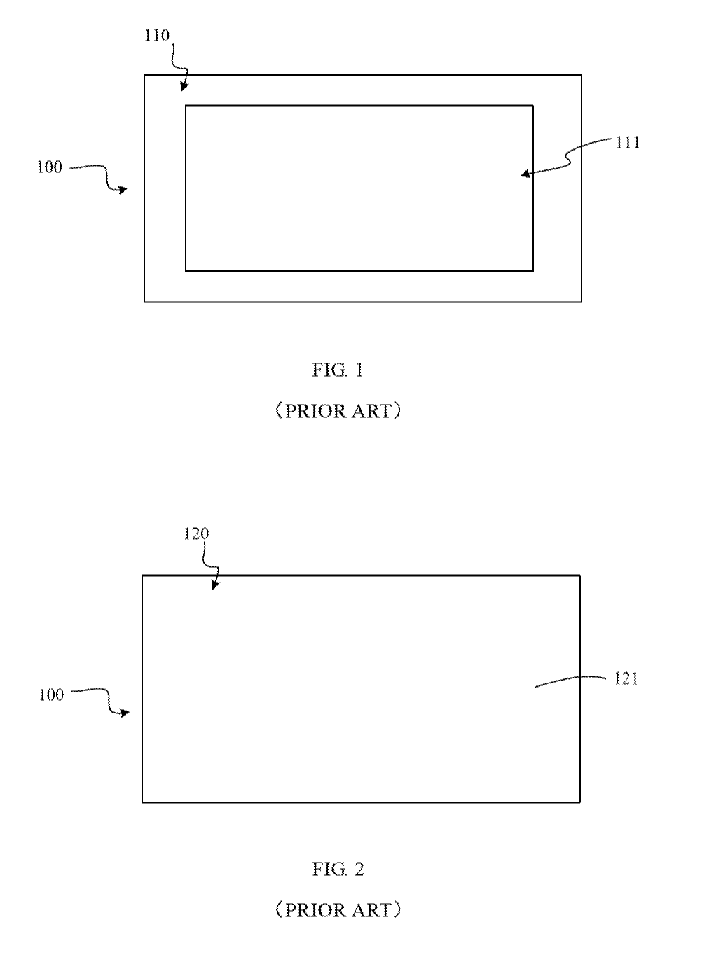

### DETAILED DESCRIPTION

The present disclosure will be further described in accordance with the figures and exemplary examples.

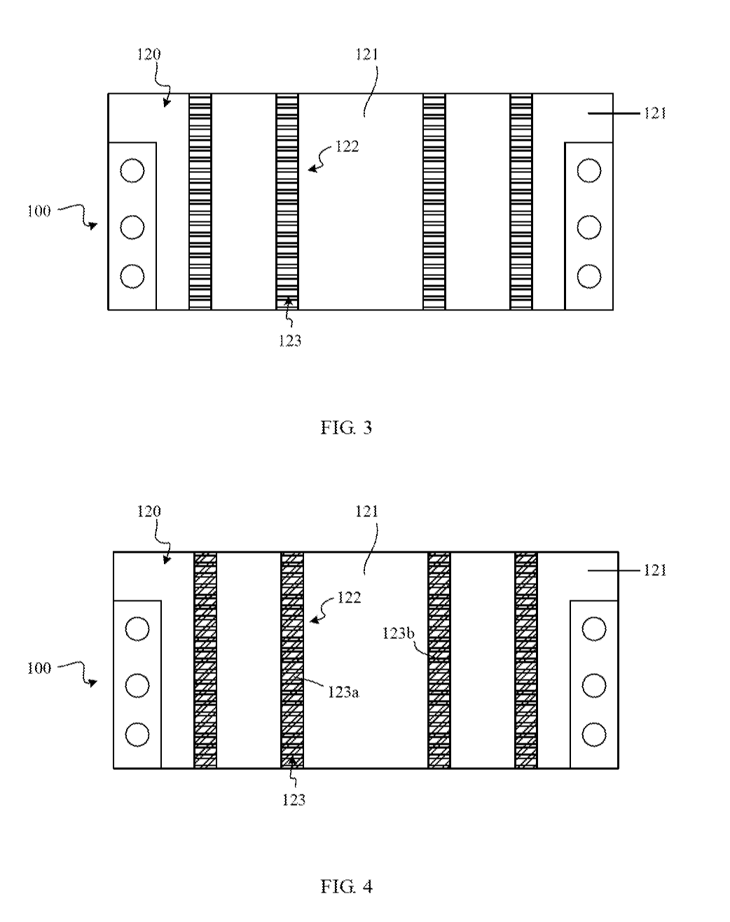

The present disclosure provides an example of a printed circuit board (PCB) in the FIG. 3, where the PCB comprises a substrate 100 and a conductive foil 121 attached to the substrate 100. The conductive foil 121 may use materials having good conductivity, such as a conductive copper foil, a conductive silver foil, and a conductive gold foil. The substrate 100 comprises a first surface 110 (reference to FIG. 1) that packages electronic components using surface mount technology (SMT) and a second surface 120 that attaches to the conductive foil 121, where the conductive foil comprises a plurality of blocks. Spacer regions 122 are arranged between the blocks, where the spacer regions 122 are configured with wires 123 for electrical connection, provide a buffer space for thermal expansion of the conductive foil 121, and make internal heat between the substrate 100 and the conductive foil 121 fast and uniformly pass out, Which effectively prevents the conductive foil 121 of the PCB falling and the substrate 100 warping, thereby improving product yield and work life of the products.

Generally, the PCB is rectangular, and also may be other shapes. The example will take a rectangular structure of the PCB for example, as shown in FIG. 3, because proportion of thermal expansion of an entire conductive foil 121 without the spacer regions 122 is great at a long edge direction, the spacer regions 122 is perpendicular to the long edge of the PCB, which provides the buffer space for thermal expansion of the conductive foil 121. The entire conductive foil 121 is divided into a plurality of blocks to avoid the conductive foil 121 falling because of great proportion of the thermal expansion of the entire conductive foil 121 and achieve uniform heat dissipation. where the heat is dissipated from the spacer regions 122 instead of being concentrated in the interval between the substrate 100 and the conductive foil 121.

In the example, the wires 123 of the spacer region 122 are arranged in the spacer region according to a same spacing, which improves electrical connection between the wires when the wires are arranged.

In order to avoid electro-magnetic interference (EMI), as shown in FIG. 4, the wires 123 of the spacer region 122 are divided into a first group wire 123a and a second group wire 123b, where the first group wire 123a and the second group wire 123b are arranged in the spacer region according to themselves same spacing. The first group wire 123a and the second group wire 123b cross each other to form a net structure, which effectively avoids the EMI.

In the example, the spacing between the wires is in a range of 0.13-0.5 mm, which effectively avoids the EMI and simplifies wire design, further avoids copper foil warping. A width of the wire is in a range of 0.13-0.5 mm, which avoids the proportion of the thermal expansion of the conductive foil 121 increasing and effectively avoids the EMI.

For the field of the display device, control requirement of cost is more than other fields, and the above-mentioned PCB of the example can be applied to the field of the display device.

The present disclosure is described in detail in accordance with the above contents with the specific exemplary examples. However, this present disclosure is not limited to the specific examples. For the ordinary technical personnel of the technical field of the present disclosure, on the premise of keeping the conception of the present disclosure, the technical personnel can also make simple deductions or replacements.

We claim:

1. A printed circuit board (PCB), comprising:
a substrate comprising a first surface that packages electronic components and a second surface opposite to the first surface; and
a conductive foil that attaches to the second surface of the substrate;
wherein the conductive foil comprises a plurality of blocks, spacer regions are arranged between the blocks, and the spacer regions are configured with wires for electrical connection.

2. The PCB of claim 1, wherein the PCB is rectangular, a long edge of the PCB is perpendicular to the spacer regions.

3. The PCB of claim 1, wherein the wires of the spacer region are arranged in the spacer region according to a same spacing.

4. The PCB of claim 1, wherein the wires of the spacer region are divided into a first group wire and a second group wire; the first group wire and the second group wire are arranged in the spacer region according to themselves same spacing, and the first group wire and the second group wire cross each other to form a net structure.

5. The PCB of claim 3, wherein the spacing between the wires is in a range of 0.13-0.5 mm.

6. The PCB of claim 3, wherein a width of the wire is in a range of 0.13-0.5 mm.

7. A display device, comprising:
one or more printed circuit boards (PCBs);
wherein the PCB comprises a substrate and a conductive foil; the substrate comprises a first surface that packages electronic components and a second surface opposite to the first surface, and the conductive foil attaches to the second surface of the substrate;
wherein the conductive foil comprises a plurality of blocks, spacer regions are arranged between the blocks, the spacer regions are configured with wires for electrical connection.

8. The display device of claim 7, wherein the PCB is rectangular, a long edge of the PCB is perpendicular to the spacer regions.

9. The display device of claim 7, wherein wires of the spacer region are divided into a first group wire and a second group wire; the first group wire and the second group wire are arranged in the spacer region according to themselves same spacing, and the first group wire and the second group wire cross each other to form a net structure.

10. The display device of claim 9, wherein spacing between the wires is in a range of 0.13-0.5 mm, and a width of the wire is in a range of 0.13-0.5 mm.
